(19) United States
(12) Patent Application Publication
(10) Pub. No.: US 2015/0305144 A1
(43) Pub. Date: Oct. 22, 2015

(54) SHIELD FILM AND SHIELD PRINTED WIRING BOARD

(71) Applicant: TATSUTA ELECTRIC WIRE & CABLE CO., LTD., Higashiosaka-shi, Osaka (JP)

(72) Inventors: Hiroshi TAJIMA, Higashiosaka-shi, Osaka (JP); Sirou YAMAUCHI, Higashiosaka-shi, Osaka (JP)

(21) Appl. No.: 14/405,774

(22) PCT Filed: Jun. 4, 2013
(86) PCT No.: PCT/JP2013/065467

§ 371 Date: Dec. 4, 2014

(30) Foreign Application Priority Data
Jun. 7, 2012 (JP) 2012-129708

(51) Int. Cl. H05K 1/02; H05K 9/00

(52) U.S. Cl. CPC H05K 1/0221; H05K 1/0298; H05K 9/0088; H05K 2201/0355

(57) ABSTRACT

Provided is a shield film having good shielding characteristics in the high frequency region, and a shield printed wiring board. A shield film, provided with, in a layered state: a plurality of metal layers (12, 14) (metal thin film (12), metal foil (14)); an insulating layer (13) disposed between the metal layers; and an electroconductive adhesive layer (15) disposed on the surface of the metal foil (14), from amongst the metal layers (12, 14), on which the insulating layer (13) is not disposed.

### TECHNICAL FIELD

The present invention relates to a shield film used in portable devices and personal computers and to a shield printed wiring board.

### BACKGROUND ART

Traditionally, shield films having a metal layer have been used in portable devices, personal computers and the like for the purpose of restraining noise and/or shielding electromagnetic waves to the outside. For example, PTL 1 discloses a complex electromagnetic wave shielding material comprising a conductive core made of metal foil whose main component is aluminum, a dry copper plated layer, and a metal plated layer sequentially formed on one side of an organic resin film from the bottom, wherein the rupture elongation is 5% or higher. Further, PTL 2 discloses a complex electromagnetic wave shielding material comprising a conductive core made of metal foil whose main component is Al, a dry Ni-alloy plated layer, a dry Cu plated layer, and a metal plated layer sequentially formed on one side of an organic resin film from the bottom, wherein the elongation is 5% or higher.

Such a shield film is pasted on to a printed-wiring board. In general, a metal layer of a shield film is electrically connected to a ground circuit of a printed-wiring board so as to stabilize the electric potential.

### CITATION LIST

### Patent Literature

[PTL 1] Japanese Unexamined Patent Publication No. 221107/2007 (Tokukai 2007-221107)

[PTL 2] Japanese Unexamined Patent Publication No. 021977/2008 (Tokukai 2008-021977)

### SUMMARY OF INVENTION

### Technical Problem

There have been demands for high-speed processing of moving pictures and for high-speed communications in portable devices, personal computers and the like. To address this issue, there have been technologies for processing a mass volume of signals (high-speed signal processing). Under such a circumstance, there are also demands for a shield film with improved ability to restrain noises to the signal lines and with improved transmission characteristics.

However, when the shield film includes a single metal layer as in the case of PTL 1 and PTL 2, the metal layer is connected to a ground circuit. This, when a strong external noise such as static electricity and the like enters, causes unstable electric potential of the ground circuit, consequently leading to unstable performance of the signal circuit.

In view of the above problem, it is an objective of the present invention to provide a shield film and a shield printed wiring board, with improved shielding characteristics.

### Technical Solution

A shield film of the present invention includes, in a layered state: a plurality of metal layers; an insulating layer disposed between the metal layers; and an electroconductive adhesive layer disposed on a surface of one of outermost metal layers, from amongst the plurality of metal layers, on which surface the insulating layer is not disposed.

The structure with a plurality of metal layers disposed and spaced from each other with the insulating layer electrically insulating them from each other provides effective prevention of the noise generated on one or the other side of the shield film or momentary high voltage electromagnetic waves in a pulse form due to static electricity, from passing through the shield film in multiple stages. The metal layers in general are connected to a wiring pattern for ground on the printed-wiring board via an electroconductive adhesive layer, and the above structure with the plurality of metal layers reduces variation in the electric potential in the wiring pattern for ground by shutting, in multiple stages, the external noise and static electricity and the like. With these effects, a favorable shielding characteristic of the shield film in a high frequency region is achieved.

The shield film of the present invention is adapted so that at least one of the metal layers is made of metal foil.

When compared to cases of making all the metal layers by a material other than metal foil, the above structure in which at least one of the plurality of metal layers is made of metal foil yields a favorable shape retentive characteristic, thus enabling favorable workability in assembling the shield film.

The shield film of the present invention is adapted so that a main component of the metal foil is copper.

The above structure allows favorable electroconductivity while enabling production of such a shield film at low costs.

The shield film of the present invention is adapted so that the metal foil is formed by rolling.

The above structure, with further improved shape retentive characteristic, allows favorable workability in assembling a substrate film such as a flexible substrate on which the shield film is pasted.

The shield film of the present invention is adapted so that the layer thickness of the metal foil is adjusted by etching.

In this structure, a metal foil of first size in its layer thickness is formed by rolling, and then made thinner to the second size by etching. This allows formation of a metal layer whose layer thickness would not be achievable by rolling.

The shield film of the present invention is adapted so that at least one of the outermost metal layers, from amongst the plurality of metal layers, is formed by metal foil.

The above structure allows favorable transmission characteristics of a printed-wiring board to which, in general, the shield film is to be pasted.

The shield film of the present invention is adapted so that the electroconductive adhesive layer is an anisotropic electroconductive adhesive layer.

The above structure improves the transmission characteristics while enabling production of such a shield film at low costs.

The shield film of the present invention further includes a protective layer protecting the other one of the outermost metal layers, from amongst the plurality of metal layers.

The above structure prevents damages by external forces, or separation of the metal layers due to variation in the shape at the time of assembling.

A shield printed wiring board of the present invention includes: a printed-wiring board having a base member on which a wiring pattern for signals and a wiring pattern for ground are formed, and an insulating film provided on the base member so as to cover the wiring pattern for signals, while keeping at least a portion of the wiring pattern for ground uncovered; and the above-described shield film provided on the insulating film on the printed-wiring board, via an electroconductive adhesive layer.

The above structure in which one of the outermost metal layers, from amongst the plurality of metal layers, is electrically connected to the wiring pattern for ground formed on the base member of the printed-wiring board via the electroconductive adhesive layer of the shield film improves the shielding performance of the shield printed wiring board.

The shield printed wiring board of the present invention is adapted so that the other one of the outermost metal layers, from amongst the plurality of metal layers, in the shield film is connected to an external ground.

With the structure, the shielding performance of the shield printed wiring board is further improved.

### BRIEF DESCRIPTION OF DRAWINGS

FIG. 1 is a schematic diagram showing a cross section of a shield film.

FIG. 2 is a schematic diagram showing a cross section of the shield printed wiring board.

FIG. 3 is a schematic diagram showing a modification of the shield film.

FIG. 4 is a schematic diagram showing yet another modification of the shield film.

FIG. 5 is a schematic diagram of yet another modification of the shield film.

FIG. 6 is a diagram showing a structure of a system of a device for evaluating electromagnetic wave shielding effect used in KEC method.

FIG. 7 is a diagram showing measurement results of electromagnetic wave shielding performance by KEC method.

FIG. 8 is a diagram showing an experimental device for measuring the shape retentive characteristics.

### DESCRIPTION OF EMBODIMENTS

The following describes a preferable embodiment of the present invention, with reference to attached drawings.

(Structure of Shield Film 1)

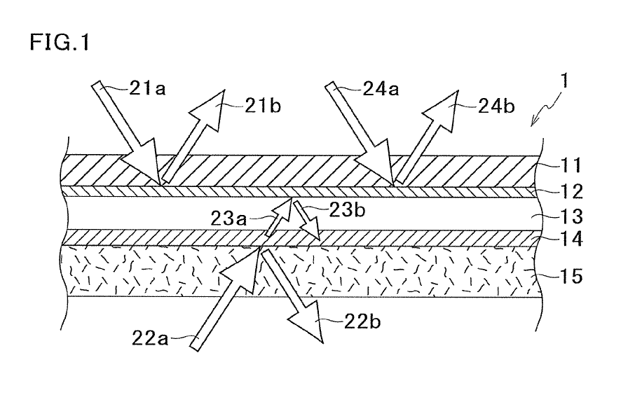

The shield film 1 shown in FIG. 1 includes, in a layered state, a plurality of metal layers 12 and 14, an insulating layer 13 disposed between the metal layers, and an electroconductive adhesive layer 15 disposed on a surface of the metal layer 14, which is one of outermost metal layers 12 and 14, on which surface the insulating layer 13 is not disposed. More specifically, the shield film 1 includes, in a layered state, the metal layers 12 and 14, the insulating layer 13 interposed between the metal layers, and the electroconductive adhesive layer 15 disposed to contact the surface of the metal layer 14, which is one of outermost metal layers 12 and 14, on which surface the insulating layer 13 is not disposed. In other words, the shield film 1 includes, in a layered state, the electroconductive adhesive layer 15 disposed on a reverse side of the side of the metal layer 14, which is one of outermost metal layers 12 and 14, on which surface the insulating layer 13 is disposed. That is, the shield film 1 includes, in a layered state, the electroconductive adhesive layer 15 disposed on a side of the metal layer 14 opposite to the side the side of the metal layer 14, which is one of outermost metal layers 12 and 14, on which surface the insulating layer 13 is disposed.

Here, the “insulating layer disposed between the metal layers” means that at least one insulating layer is disposed between any metal layers. That is, there may be metal layers which are stacked on one another.

Note that the insulating layer 13 disposed between the metal layers 12 and 14 does not necessarily have to be in contact with the metal layers 12 and 14. That is, a layer made of another material (a layer having another function) may be disposed between the metal layer 12 and the insulating layer 13, and/or between the insulating layer 13 and the metal layer 14.

Further, the metal layer 14 and the electroconductive adhesive layer 15 do not necessarily have to be in contact with each other. That is, a layer made of another material (a layer having another function) may be disposed between the metal layer 14 and the electroconductive adhesive layer 15.

Examples of “a layer made of another material (a layer having another function)” include an adhesive layer for combining the above mentioned layers. For example, unlike the embodiment dealing with a case where the insulating layer having an insulative function has an adhering function, if the insulating layer is a film or the like having no adhering function, an adhesive layer is provided between the insulating layer and the metal layer.

Note that, in the embodiment, the shield film includes two metal layers; however, the present invention is not limited to this and there may be three or more metal layers.

Further, at least one of the metal layers is preferably made of metal foil. In the embodiment, the metal layer 12 is made of a metal thin film, while the metal layer 14 is made of a metal foil. The metal layer 12 may be hereinafter also referred to as metal thin film 12. Further, the metal layer 14 may be hereinafter also referred to as metal foil 14.

Further, the shield film 1 has a protective layer 11 for protecting the metal layer 12. In other words, the shield film 1 has a protective layer 11 which protects the metal layer 12 which is the other one of outermost metal layers 12 and 13.

The following details each structure.

(Protective Layer 11)

The protective layer 11 is an insulating layer constituted by a coating layer made of a cover film and/or an insulative resin.

The cover film is made of an engineering plastic. Examples of an engineering plastic include: polypropylene, cross-linked polyethylene, polyester, polybenzimidazole, aramid, polyimide, polyimidoamide, polyetherimide, polyphenylenesulphide (PPS), polyethylenenaphthalate (PEN).

If heat resistance is not required so much, a low-cost polyester film is preferable. In cases where incombustibility is required, a polyphenylenesulphide film is preferable, and if heat resistance is further required, an aramid film or a polyimide film is preferable.

The insulative resin may be any resin as long as it is insulative. Examples of such a resin include: a thermosetting resin or an ultraviolet curable resin, and the like. Examples of the thermosetting resin include a phenol resin, an acrylic resin, an epoxy resin, a melamine resin, a silicon resin, acrylic modification silicon resin, and the like. Examples of the ultraviolet curable resin include: an epoxy acrylate resin, a polyester acrylate resin, and methacrylate modification of these. Note that the mode of hardening may be any mode such as thermosetting, ultraviolet curing, electron beam curing, as long as the resin is hardened.

Note that the lower limit of the thickness of the protective layer 11 is preferably 1 μm, more preferably 5 μm, and even more preferably 5 μm. Further, the upper limit of the thickness of the protective layer 11 is preferably 10 μm, and more preferably 7 μm.

(Metal Thin Film 12)

Examples of the metal material forming the metal thin film 12 include: nickel, copper, silver, tin, gold, palladium, aluminum, chrome, titanium, zinc, and an alloy including any one or more of these materials. Note that silver is especially preferable as the material for the metal thin film 12. This is because the shielding characteristic is ensured even when the layer thickness is small. Examples of a method for forming the metal thin film 12 include: electroplating, electroless plating, spattering, electron-beam evaporation method, vacuum evaporation method, CVD, metal organic, and the like. However, in terms of mass productivity, vacuum evaporation method that enables stable formation of metal thin film at low costs is preferable.

Note that the lower limit of the thickness of the metal thin film 12 is preferably 0.08 μm, more preferably 0.1 μm, and even more preferably 0.15 μm. Further, the upper limit of the thickness of the metal thin film 12 is preferably 0.5 μm.

(Insulating Layer 13)

The insulating layer 13 is an adhesive agent, and is formed by a polystyrene-based, vinyl acetate-based, polyester-based, polyethylene-based, polypropylene-based, polyamide-based, rubber-based, or acryl-based thermoplastic resin, or a phenol-based, epoxy-based, urethane-based, melamine-based, alkyd-based thermosetting resin, and the like. Note that the adhesive agent may be any one of the above listed resin or a mixture of them. Further, the adhesive agent may further contain an adhesiveness imparting agent. Examples of the adhesiveness imparting agent include a tackifier such as a fatty acid hydrocarbon resin, a C5/C9 mixture resin, rosin, a rosin derivative, a terpene resin, an aromatic series-based hydrocarbon resin, a thermal-reactive resin, and the like.

The lower limit of the thickness of the insulating layer 13 is preferably 3 μm, and is more preferably 5 μm. Further, the upper limit of the thickness of the insulating layer 13 is preferably 50 μm, more preferably 30 μm, and even more preferably 15 μm.

Note that the insulating layer 13 is not limited to an adhesive agent, and may be “a layer made of another material (a layer having another function)” described hereinabove. For example, the insulating layer 13 may be such that an adhesive layer is provided on both sides of an engineering plastic. Examples of the material for the engineering plastic include a resin such as polyethylene terephthalate, polypropylene, cross-linked polyethylene, polyester, polybenzimidazole, polyimide, polyimidoamide, polyetherimide, polyphenylenesulphide (PPS), and the like. If heat resistance is not required so much, a low-cost polyester film is preferable. In cases where incombustibility is required, a polyphenylenesulphide film is preferable, and if heat resistance is further required, an aramid film or a polyimide film is preferable.

(Metal Foil 14)

The metal foil 14 is preferably formed by rolling. This way, the shield film is able to possess a favorable shape retentive characteristic, which improves the workability at the time of assembling flexible substrates and the like having shield film pasted thereon. For example, when a flexible printed-wiring board having the shield film is assembled to a portable device and the like while the flexible printed-wiring board is bent, the favorable shape retentive characteristic of the shield film allows the flexible printed-wiring board to maintain the bent state. Therefore, a worker does not have to retain the bent state of the flexible printed-wiring board, and the burden in the work of assembling the portable device and the like is reduced, which leads to an improved workability. If the metal foil 14 is formed by rolling, the layer thickness of the metal foil 14 is preferably adjusted by etching.

The metal material for forming the metal foil 14 preferably contains copper as the main component. This realizes a favorable electroconductivity, while enabling production of the shield film at low costs. Note that the metal foil 14 however is not limited to one whose main component is copper, and may contain any of the nickel, copper, silver, tin, gold, palladium, aluminum, chrome, titanium, and zinc, or an alloy containing two or more of these materials.

Note that the metal foil 14 does not necessarily have to be metal foil formed by rolling, and may be a metal layer formed by a special electroplating so as to have a structure in which crystals are spread in a surface direction as in the case of the metal foil. Doing so will also yield a favorable shape retentive characteristic as the metal foil formed by rolling.

Note further that the lower limit of the thickness of the metal foil 14 is preferably 1 μm, and more preferably 2 μm. Further, for the sake of sliding characteristic, the upper limit of the thickness of the metal foil 14 is preferably 6 μm, and more preferably 3 μm.

(Electroconductive Adhesive Layer 15)

The electroconductive adhesive layer 15 is preferably an anisotropic electroconductive adhesive layer having anisotropic electroconductivity which ensures electroconductivity only in the thickness directions, in terms of transmission characteristics and costs; however, the electroconductive adhesive layer 15 is not limited to this. For example, the electroconductive adhesive layer 15 may be an isotropic electroconductive adhesive layer having isotropic electroconductivity which ensures electroconductivity in all directions in three dimensions including the thickness, width, and the length directions. The electroconductive adhesive layer 15 here is formed as an anisotropic electroconductive adhesive layer by adding flame retardant and conductive filler to the adhesive agent.

When the shield film 1 is applied to an FPC (flexible printed-wiring board), the lower limit of the thickness of the electroconductive adhesive layer 15 is preferably 2 μm, and more preferably 3 μm. Further, the upper limit of the thickness of the electroconductive adhesive layer 15 is preferably 15 μm, and more preferably 9 μm.

Examples of the adhesive agent contained in the electroconductive adhesive layer 15, as an adhesive resin, include the layer similar to that in the insulating layer 13. Further, the conductive filler added to the electroconductive adhesive layer 15 is partially or entirely made of a metal material. Example of the conductive filler include: copper powder, silver powder, nickel powder, silver coated copper powder (Ag coated Cu powder), gold coated copper powder, silver coated nickel powder (Ag coated Ni powder), gold coated nickel powder. These metal powders are produced by atomizing or a carbonyl process. To add these, metal powder coated with a resin or a resin coated with metal powder is also adoptable. Further to the electroconductive adhesive layer 15 may be added and mixed one or more types of conductive fillers. Note that the conductive filler is preferably Ag coated Cu powder or Ag coated Ni powder. This way, particles with stable electroconductivity are obtained with a low-cost material.

In cases of anisotropic electroconductive adhesive layer, the amount of the conductive filler added falls within a range of 3 wt % to 39 wt % of the entire volume of the electroconductive adhesive layer 15. In cases of isotropic electroconductive adhesive layer, this amount will be more than 39 wt % of the entire volume of the electroconductive adhesive layer 15. Further, the average grain diameter of the conductive filler is preferably within a range of 2 μm to 20 μm; however, is set to an optimum value according to the thickness of the electroconductive adhesive layer 15. The shape of the metal filler may be in any shape including a spherical shape, needle-shape, fiber-shape, flake-shape, or dendrite shape.

As described, the shield film 1 includes the metal thin film 12 and the metal foil 14, and an insulating layer 13 between the metal thin film 12 and the metal foil 14. For example, as shown in FIG. 1, external static electricity 21a and electromagnetic waves 24a having entered the protective layer are first reflected as static electricity 21b and electromagnetic waves 24b at the border between the protective layer 11 and the metal thin film 12, respectively. Further, internal electromagnetic waves 22a having entered the electroconductive adhesive layer 15 is first reflected as the electromagnetic waves 22b at the border between the electroconductive adhesive layer 15 and the metal foil 14. Even if there are electromagnetic waves 23a out of the electromagnetic wave 22a, not reflected at the reflecting point of the metal foil 14, such electromagnetic waves 23a are reflected as electromagnetic waves 23b at the border between the insulating layer 13 and the metal thin film 12.

This, when viewed from a different point view point, means that the metal thin film 12 and the metal foil 14 form a capacitor in the shield film 1. That is, regarding the external noises, static electricity and the like, it is possible to shut the direct current component in a direction perpendicular to a surface direction of the metal layer.

(Structure of Shield Printed Wiring Board 10)

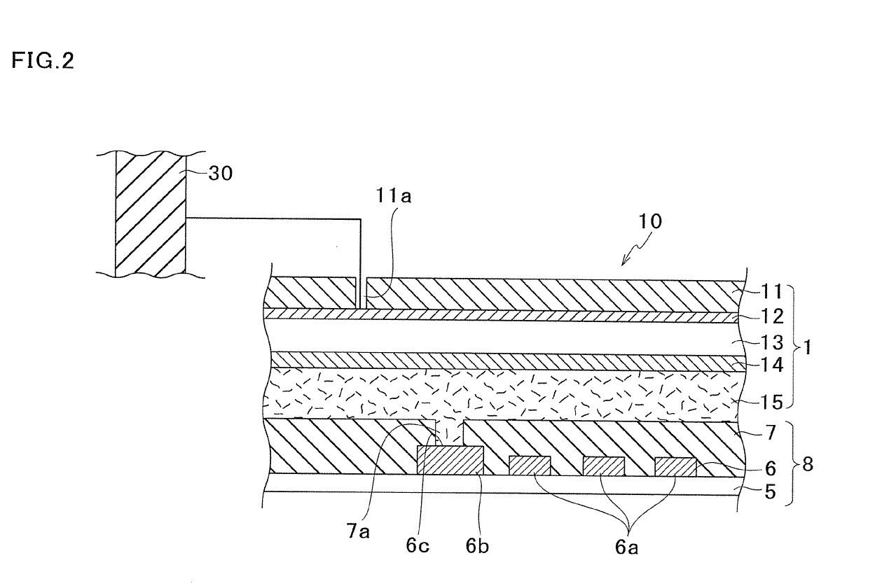

Next, with reference to FIG. 2, the following describes a shield printed wiring board 10 in which the above-described shield film 1 is pasted to an FPC (flexible printed-wiring board). Although the embodiment deals with a case where the shield film is pasted to an FPC, the present invention is not limited to this. For example, the shield film is also applicable to a COF (Chip-On-Flex), an RF (Rigid Flexible Printed Board), a multiple-layered flexible substrate, a rigid substrate, and the like.

As shown in FIG. 2, the shield printed wiring board 10 has the above-described shield film 1 stacked on a substrate film (FPC) 8. The substrate film 8 includes a base film 5, a printed circuit board 6, and an insulating film 7 stacked in this order.

As shown in FIG. 2, the surface of the printed circuit board 6 has a signal circuit 6a and a ground circuit 6b, and is covered by the insulating film 7 except for at least a part of the ground circuit 6b (non-insulative portion 6c). Further, the insulating film 7 has an insulation removed portion 7a into which a part of the electroconductive adhesive layer 15 of the shield film 1 flows. This way, the ground circuit 6b and the metal foil 14 are electrically connected to each other.

The wiring patterns of the signal circuit 6a and the ground circuit 6b are formed by etching the conductive material. The ground circuit 6b here means a pattern which maintains the ground potential. That is, the base film 5 has a ground circuit 6b which is a wiring pattern for ground.

That is, the shield printed wiring board 10 includes: a base member (base film 5) having a wiring pattern for signals (signal circuit 6a) and a wiring pattern for ground (ground circuit 6b); and an insulating film 7 provided on the base member in such a manner as to cover the wiring pattern for signals while keeping at least a part of the wiring pattern for ground uncovered. On the insulating film 7 is provided the shield film 1 via the adhesive of the electroconductive adhesive layer 15.

Further, the protective layer 11 of the shield film 1 has a protective layer removed portion 11a which is opened in a direction corresponding to the direction of stacking. Thus, with the provision of the protective layer removed portion 11a to the protective layer 11, the metal thin film 12 which is an outermost metal layers, from amongst the plurality of metal layers, has a portion whose surface is exposed to the outside. The surface of the portion of the metal thin film 12 exposed is electrically connected, via wiring or the like, to a casing 30 in which the shield printed wiring board 10 is mounted. This way, the metal thin film 12 is connected to the external ground.

As described, the metal thin film 12 and the metal foil 14 are both connected to the ground. This further reinforces the shielding performance.

Note that all the metal layers including the metal thin film 12 and the metal foil 14 are preferably connected to the ground; however, the present invention is not limited to such a structure. For example, a structure in which none of the metal layers are connected to the ground and a structure in which one of the metal layers is connected to the ground are possible.

Note that the base film 5 and the printed circuit board 6 may be combined by using an adhesive agent, or jointed as in the case of a so-called non-adhesive agent copper clad layered product plate which uses no adhesive agent. Further, the insulating film 7 may be formed by pasting a flexible insulating film by using an adhesive agent, or by subjecting a photosensitive insulative resin to a series of processes including, for example, applying, drying, exposing, developing, and thermal treatment. When the insulating film 7 is pasted by using an adhesive agent, the insulation removed portion 7a is formed also in the adhesive agent, in the position of the ground circuit 6b. Further, the present invention may be implemented by suitably adopting, as the substrate film 8: a single-sided FPC having a printed circuit board only one side of the base film; a double-sided FPC having a printed circuit board on both sides of the base film; a multiple-layered FPC having multiple layers of these FPCs; a flex board (®) having a multiple-layered component mounted part and a cable part; a flex rigid substrate in which members structuring a multiple-layered part are made of a rigid material; or a TAB tape for tape carrier packages.

Further, the base film 5 and the insulating film 7 are both made of an engineering plastic. Examples of such an engineering plastic include: a resin such as polyethylene terephthalate, polypropylene, cross-linked polyethylene, polyester, polybenzimidazole, polyimide, polyimidoamide, polyetherimide, polyphenylenesulphide (PPS). If heat resistance is not required so much, a low-cost polyester film is preferable. In cases where incombustibility is required, a polyphenylenesulphide film is preferable, and if heat resistance is further required, an aramid film or a polyimide film is preferable.

Note that the lower limit of the thickness of the base film 5 is preferably 10 μm, and more preferably 20 μm. Further, the upper limit of the thickness of the base film 5 is preferably 60 μm, and more preferably 40 μm.

Further, the lower limit of the thickness of the insulating film 7 is preferably 10 μm, and more preferably 20 μm. Further, the upper limit of the thickness of the insulating film 7 is preferably 60 μm, and more preferably 40 μm.

(Manufacturing Method of Shield Film 1)

The following describes an example manufacturing method of the shield film 1 of the embodiment.

First, the protective layer 11 is formed by heating (aging process) an insulative resin or the like applied to a mold-releasing film (not shown). The method of applying the resin is not particularly limited; however, is preferably done by using a coating apparatus such as LIP Coater and Comma Coater. Then, on the surface of the protective layer 11 opposite to the mold-releasing film is formed a metal thin film 12 by vaporization of silver and the like. This way, a first layered product sequentially including the mold-releasing film, the protective layer 11, and the metal thin film 12 is manufactured.

Meanwhile, a metal foil 14 is formed by rolling copper between rotating rollers to reduce the thickness of the copper to a first size. The lower limit of the thickness of this first size is preferably 3 μm, more preferably 6 μm, and even more preferably 9 μm. Further, the upper limit of the thickness of the first size is preferably 35 μm, more preferably 18 μm, and even more preferably 12 μm.

To the copper foil whose thickness is reduced to the first size by rolling is pasted a film made of polyethylene terephthalate or the like, and etching is conducted to the film. Through this, a metal foil 14 whose thickness is reduced to a second size (0.5 μm to 12 μm) is formed. Specifically, the copper foil 6 μm is dipped into an etching liquid such as sulfuric acid and a hydrogen peroxide solution, to process the foil to the foil with a thickness of 2 μm. Note that the surface of the copper foil having been etched is preferably subjected to modification of its adhesiveness by conducting thereto a plasma treatment.

Further, a surface one side of the metal foil 14 is coated with an insulating layer 13. Further, to the surface on the other side of the metal foil 14 is pasted a not-shown protection film such as polyethylene terephthalate, using an acrylic adhesive agent.

This way a second layered product sequentially including the insulating layer 13, the metal foil 14, and the protection film is manufactured.

Then, the insulating layer 13 of the second layered product is pasted to the metal thin film 12 of the first layered product, and laminating is conducted thereto. Thus, the insulating layer 13 is solidified through an aging process. Then, the protection film on the metal foil 14 is removed, and an electroconductive adhesive agent is applied to form an electroconductive adhesive layer 15. This way, a shield film 1 having a mold-releasing film pasted on the protective layer 11 is manufactured.

(Manufacturing Method of Shield Printed Wiring Board 10)

First, an insulation removed portion 7a is formed by making a hole on the insulating film 7 of the substrate film 8, by laser machining and the like. This causes a portion of the ground circuit 6b in the insulation removed portion 7a to be exposed to the outside.

Then, an electroconductive adhesive layer 15 of the shield film 1 is adhered to the insulating film 7 of the substrate film 8. In this process of adhering, the substrate film 8 and the shield film 1 are press joined from the top and bottom by using a pressing machine, while the shield film 1 is heated. This way, the electroconductive adhesive layer 15 of the shield film 1 is softened by the heat of the heater, and the pressure applied by the pressing machine adheres the electroconductive adhesive layer 15 of the shield film 1 to the insulating film 7. At this time, the insulation removed portion 7a is filled with a part of the softened electroconductive adhesive layer 15. Thus, the part of the ground circuit 6b exposed in the insulation removed portion 7a is adhered to the electroconductive adhesive layer 15 filled up. As such, the ground circuit 6b is electrically connected to the metal foil via the electroconductive adhesive layer 15. The mold-releasing film is removed at a suitable timing; e.g, when shipping, when arranging the shield film on the shield printed wiring board 10, and the like.

Thus, an embodiment of the present invention is described hereinabove. Note however that the present invention is not necessarily limited to the above embodiment.

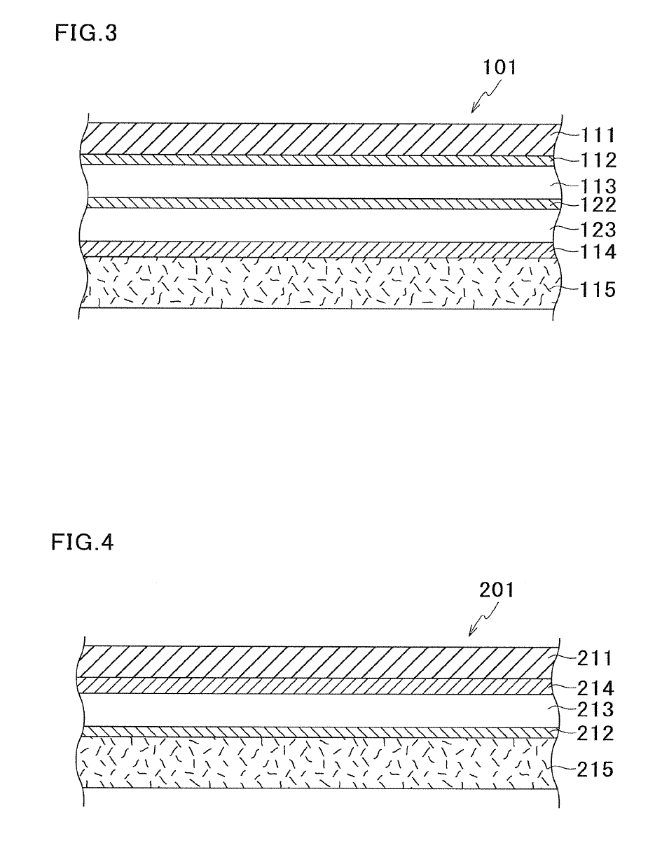

For example, the above embodiment deals with a case where the shield film 1 has two metal layers, i.e., the metal thin film 12 and the metal foil 14; however, the present invention is not limited to this. The shield film may have three or more metal layers. FIG. 3 shows a shield film 101 having three metal layers. As shown in FIG. 3, the shield film 101 is formed by sequentially stacking a protective layer 111, a metal thin film 112, an insulating layer 113, a metal thin film 122, an insulating layer 123, a metal foil 114, and an electroconductive adhesive layer 115. This forms more surfaces with discontinuous impedance than a case of two metal layers. As the result, there will be more reflecting points, improving the shielding characteristics with respect to the internal and external noises and static electricity. Note that, although illustration is omitted, there may be four or more metal layers, with any of these metal layers being metal foil.

Further, as shown in FIG. 3, the metal foil 114 is an outermost metal layer amongst the plurality of metal layers (on the side where the printed-wiring board is disposed). This improves the transmission characteristics of printed-wiring boards in general to which the shield film is pasted. Further, the embodiment deals with a case where the metal layers in the shield film 1 have different layer thicknesses, respectively; however, the present invention is not limited to this, and metal layers having the identical layer thickness may be adopted.

Further, for example, the embodiment deals with a case where the metal layer of the shield film 1 disposed closest to the base film 5 is made as the metal foil 14; however, the present invention is not limited to this and the metal foil 14 may be any of the metal layers. FIG. 4 shows a shield film 201 having two metal layers, one of which closest to the side of the base film 5 is not metal foil. As shown in FIG. 4, the shield film 201 is formed by sequentially stacking a protective layer 211, a metal foil 214, an insulating layer 213, a metal thin film 212, and an electroconductive adhesive layer 215. This improves the shape retentive characteristic of the shield printed wiring board 10.

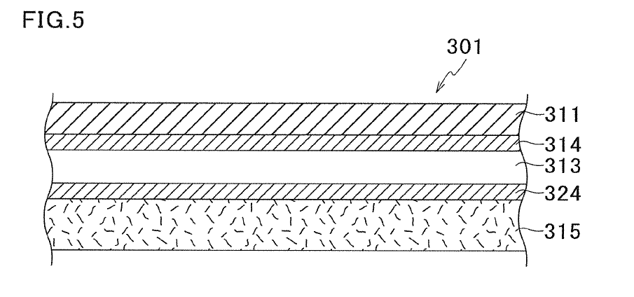

Further, FIG. 5 shows a shield film 301 in which two metal layers are both metal foil. As shown in FIG. 5, the shield film 301 is formed by sequentially stacking a protective layer 311, a metal foil 314, an insulating layer 313, a metal foil 324, and an electroconductive adhesive layer 315. This further improves the shape retentive characteristic of the shield printed wiring board 10.

Further, the embodiment deals with a case where the shield film 1 is pasted on one side of the shield printed wiring board 10; however, the present invention is not limited to this. For example, the shield film may be pasted to both sides.

Embodiment and modifications of the present invention thus described above solely serve as specific examples of the present invention, and are not to limit the scope of the present invention. The specific structures and the like of the present invention are suitably modifiable. Further, the actions and effects of the present invention described in the above embodiment are no more than examples of preferable actions and effects brought about by the present invention, and the actions and effects of the present invention are not limited to those described hereinabove. [Example]

(Electromagnetic Wave Shielding Characteristics)

Next, the following specifically describes electromagnetic wave shielding characteristics of the present invention, using Examples 1 to 3 and Comparative Examples 1 and 2 of the shield film of the embodiment.

Note that, in each of the Comparative Examples 1 and 2, and Examples 1 to 3, shield films (measurement test piece) 401 shown in Table 1 were used. Note further that the numeric values in Table 1 indicate the layer thickness of each structure (each layer). Further, the materials of the metal layers are shown under the layer thickness value in Table 1.

In Comparative Examples 1 and 2 was used a layered product in which a protective layer, a metal layer, and an electroconductive adhesive layer were sequentially stacked. An epoxy based resin was used for the protective layer, and anisotropic electroconductivity for the electroconductive adhesive layer, in Comparative Examples 1 and 2. The metal layers used were a copper foil of 2 μm, a silver plated layer of 0.1 μm, as shown in Table 1. Note that the copper foil was a rolled copper foil formed by rolling.

In Examples 1 to 3 was used a layered product in which a protective layer, a metal layer (first metal layer), an insulating layer, a metal layer (second metal layer), and an electroconductive adhesive layer are sequentially stacked. An epoxy resin of 27.5 μm was used as the insulating layer, in Examples 1 to 3. The first metal layers used were and the second metal layers were copper foil of 2 μm, a silver plated layer of 0.1μ, and a silver plated layer of 0.1μ, respectively, and the second metal layers used were copper foil of 2 μm, copper foil of 2 μm, and a silver plated layer of 0.1μ, as shown in Table 1.

As shown in Table 1, an epoxy based resin of 5 μm was used as the protective layer. Further, as the electroconductive adhesive layer was used an adhesive agent of 5 μm having anisotropic electroconductivity.

TABLE 1

| | Comp. | | | | |
|---|---|---|---|---|---|
| | Exam- | Comp. | Exam- | Exam- | Exam- |
| Structure | ple 1 | Example 2 | ple 1 | ple 2 | ple 3 |
| Protective layer (μm) | 5 | 5 | 5 | 5 | 5 |
| First metal layer (μm) | 2 | 0.1 | 2 | 0.1 | 0.1 |
| | Cu | Ag | Cu | Ag | Ag |
| Insulating layer (μm) | — | — | 27.5 | 27.5 | 27.5 |
| Second metal layer | — | — | 2 | 2 | 0.1 |
| (μm) | | | Cu | Cu | Ag |
| Electroconductive | 9 | 9 | 9 | 9 | 9 |
| adhesive layer (μm) | | | | | |

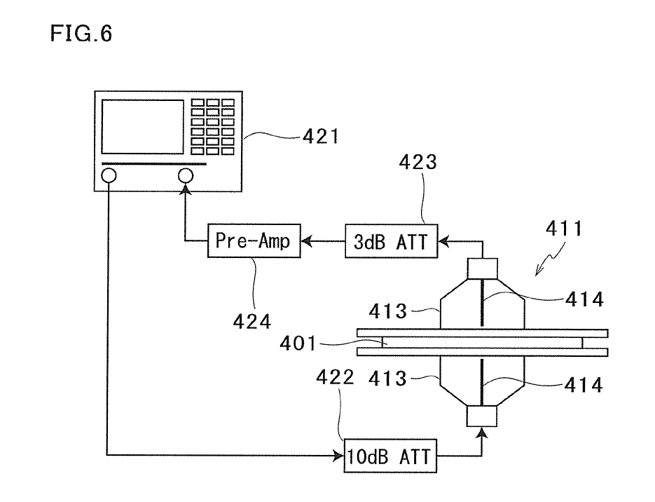

Then, a KEC method using an electromagnetic wave shielding effect measurement device 411 developed by KEC Electronic Industry Development Center was adopted to evaluate the electromagnetic wave shielding characteristics of the shield films. FIG. 6 is a diagram showing a structure of the system used in the KEC method. The system used in the KEC method includes: the electromagnetic wave shielding effect measurement device 411, a spectrum analyzer 421, an attenuator 422 for attenuation of 10 dB, and attenuator 423 for attenuation of 3 dB, and a pre-amplifier 424.

As the spectrum analyzer 421 was adopted U3741 produced by Advantest Corporation. Further, HP8447F produced by Agilent Technologies was used as the pre-amplifier 424.

As shown in FIG. 6, to the electromagnetic wave shielding effect evaluation device 411 are provided two fixtures 413 so as to face each other. Between these fixtures 413, shield films (measurement test piece) 401, i.e., the measurement subjects shown, in Table 1 are interposed. The fixture 413 adopts dimension distribution of TEM Cell (Transverse ElectroMagnetic Cell), and has a symmetrical structure on the left and right within surfaces perpendicular to the axial direction of transmission. However, to prevent formation of shortcircuit by insertion of the measurement test piece 401, a planar center conductor 414 is arranged for each fixture 413, with a space between the center conductor 414 and the fixture 413.

The shield films 401 for use in the measurements in Comparative Examples 1 and 2, and Examples 1 to 3 were each cut in 15 cm square pieces. Further, the measurements were conducted within a frequency region of 1 MHz to 1 GHz. Further, the measurements were conducted in an atmosphere where the temperature was 25° C., and the relative temperature was 30 to 50%. During the measurements, the metal layer of every the shield film 401 was connected to the ground.

In the KEC method, signals output from the spectrum analyzer 421 is input to the fixture 413 or the fixture 415 on the transmission end, via the attenuator 422. Then, the signals are received by the fixture 413 or the fixture 415 on the reception end, input to the amplified in the pre-amplifier 424 via the attenuator 423. The signals input to the pre-amplifier 424 are then amplified and subjected to measurement of signal levels in by the spectrum analyzer 421. It should be noted that, with the state of having no shield film in the electromagnetic wave shielding effect measurement device 411 as the reference, the spectrum analyzer 421 outputs the amount attenuated while the shield film is placed in the electromagnetic wave shielding effect measurement device 411.

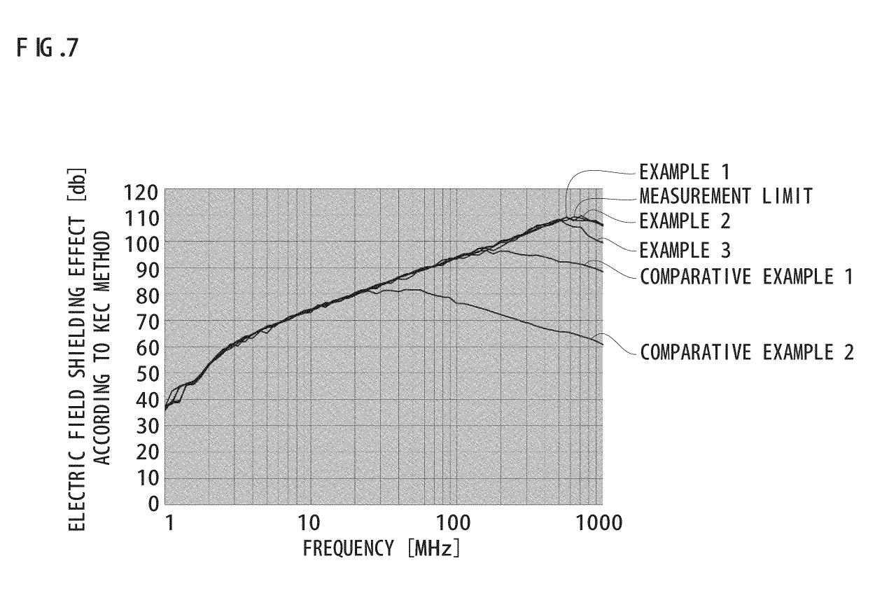

FIG. 7 shows the measurement results of electromagnetic wave shielding performance and measured by the KEC method, and the measurement limit of the spectrum analyzer 421. Referring to the figure, it should be understood that amount of attenuation in Examples 1 to 3 are greater than those of Comparative Examples 1 and 2 in a frequency region of over 100 MHz. Therefore, the shield films of Examples 1 to 3 are found to have more effective shielding characteristics than those of the Comparative Examples 1 and 2 in a high frequency region of over 100 MHz.

Further, Examples 1 and 2 in which at least one of the plurality of metal layers is a rolled copper foil also reached the measurement limit at 1 GHz. This shows that the shielding characteristics are further improved by using a rolled copper foil as at least one of the plurality of metal layers.

(Shape Retentive Characteristic)

Next, the shape retentive characteristics of the shield films were evaluated. Note that the shield film was pasted on to both sides of a polyimide film of 50 μm to form a test piece 51 having two metal layers. The test piece 51 was cut in 10 mm×100 mm for use.

TABLE 2

| | | Examples | | | | | | |
|---|---|---|---|---|---|---|---|---|
| Struc- | Insulating layer (μm) | 5 | 5 | 5 | 5 | 5 | 5 | 5 |
| ture | Type of metal layers | rolled Cu | rolled Cu | rolled Cu | rolled Cu | rolled Cu | rolled Cu | Ag plated |
| | and thickness (μm) | foil 0.5 | foil 1 | foil 2 | foil 3 | foil 6 | foil 6 | layer 0.1 |
| | Type of electroconductive | anisotropic | anisotropic | anisotropic | anisotropic | anisotropic | isotropic | anisotropic |
| | adhesive layer and | 9 | 9 | 9 | 9 | 9 | 9 | 9 |
| | thickness (μm) | | | | | | | |

| | | | | | | | |
|---|---|---|---|---|---|---|---|
| Results | ◯ | ◯ | ◯ | ◯ | ◯ | ◯ | Δ |

As shown in Table 2, the shield films used each sequentially included: a protective layer (5 μm), a metal layer (rolled copper foils of 0.5 μm, 1 μm, 2 μm, 3 μm, or 6 μm, or a silver plated layer of 0.1 μm), and a electroconductive adhesive layer (anisotropic layer or isotropic layer of 9 μm).

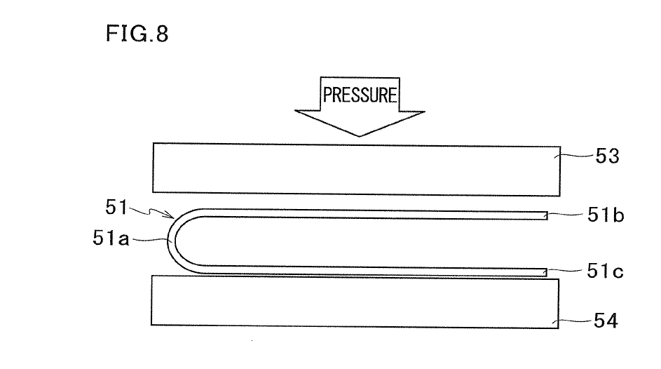

As shown in FIG. 8, the test piece 51 was bent to slightly form a crease at a bent portion 51a nearby the middle of the test piece 51 relative to its length (about 50 mm) so that a upper portion 51b and a lower portion 51c parted by the bent portion 51a faced each other.

The entire test piece 51 was placed on a PP (polypropylene) substrate 54, and SUS plates (not shown) of 0.3 mm in thickness were disposed on both sides of the test piece 51, in parallel to the length of the test piece 51. Then, silicon rubber 53 is descended from the above to press the entire test piece 51 along with the SUS plates. That is, with the presence of the SUS plates of 0.3 mm, the bend radius at the bent portion 51a of the test piece 51 was 0.15 mm.

The pressure applied by the pressing machine was 0.1 MPa and 0.3 MPa, and in each of the cases, pressurizing period was 1 sec., 3 sec., 5 sec. After the pressing, the angle (return angle) formed by the upper portion 51b and the lower portion 51c of the test piece 51 was measured.

The resulted return angles are shown in Table 2. To evaluate the test piece with the film on both sides, a circle was given in cases with the resulting return angle of 90 degrees or less, and a triangle was given in cases with the resulting return angle of over 120 degrees. According to Table 2, the ones with the rolled copper foils exhibited better shape retentive characteristics. This shows that the rolled copper foil is effective in terms of shape retentive characteristic.

### REFERENCE SIGNS LIST

1, 101, 201, 301: Shield Film
5: Base Film
6: Printed Circuit Board
6a: Signal Circuit
6b: Ground Circuit
6c: Non-Insulative Portion
7: Insulating Film
7a: Insulation Removed Portion
8: Substrate Film
10: shield printed wiring board
11, 111, 211, 311: Protective Layer
11a: Protective Layer Removed Portion
12, 112, 122, 212: Metal Thin Film
13, 113, 123, 213, 313: Insulating Layer
14, 114, 214, 314, 324: Metal Foil
15, 115, 215, 315: Electroconductive Adhesive Layer
30: Casing

1. A shield film, comprising, in a layered state:
a plurality of metal layers;
an insulating layer disposed between the metal layers; and
an electroconductive adhesive layer disposed on a surface of one of outermost metal layers, from amongst the plurality of metal layers, on which surface the insulating layer is not disposed.

2. The shield film according to claim 1, wherein at least one of the metal layers is made of metal foil.

3. The shield film according to claim 2, wherein a main component of the metal foil is copper.

4. The shield film according to claim 2, wherein the metal foil is formed by rolling.

5. The shield film according to claim 2, wherein the layer thickness of the metal foil is adjusted by etching.

6. The shield film according to claim 2, wherein at least one of the outermost metal layers, from amongst the plurality of metal layers, is formed by metal foil.

7. The shield film according to claim 1, wherein the electroconductive adhesive layer is an anisotropic electroconductive adhesive layer.

8. The shield film according to claim 1, further comprising a protective layer protecting the other one of the outermost metal layers, from amongst the plurality of metal layers.

9. A shield printed wiring board, comprising:
a printed-wiring board having a base member on which a wiring pattern for signals and a wiring pattern for ground are formed, and an insulating film provided on the base member so as to cover the wiring pattern for signals, while keeping at least a portion of the wiring pattern for ground uncovered; and
a shield film according to claim 1 provided on the insulating film on the printed-wiring board, via an electroconductive adhesive layer.

10. The shield printed wiring board according to claim 9, wherein the other one of the outer most metal layers, from amongst the plurality of metal layers, in the shield film is connected to an external ground.
